(19) United States
(12) Patent Application Publication
(10) Pub. No.: US 2011/0156052 A1
(43) Pub. Date: Jun. 30, 2011

(54) Semiconductor device having JFET and method for manufacturing the same

(75) Inventors: Rajesh Kumar Malhan, Nagoya-city (JP); Yuuichi Takeuchi, Obu-city (JP); Naohiro Sugiyama, Nagoya-city (JP)

(73) Assignee: DENSO CORPORATION, Kariya-city (JP)

(21) Appl. No.: 12/926,894

(22) Filed: Dec. 16, 2010

(30) Foreign Application Priority Data
Dec. 25, 2009 (JP) 2009-294797

(51) Int. Cl. H01L 29/24; H01L 29/80; H01L 21/337

(52) U.S. Cl. 257/77; 257/256; 438/186; 257/E29.31; 257/E29.104; 257/E21.445

(57) ABSTRACT

A semiconductor device having a JFET includes: a substrate made of semi-insulating semiconductor material; a gate region in a surface portion of the substrate; a channel region disposed on and contacting the gate region; a source region and a drain region disposed on both sides of the gate region so as to sandwich the channel region, respectively; a source electrode electrically coupled with the source region; a drain electrode electrically coupled with the drain region; and a gate electrode electrically coupled with the gate region. An impurity concentration of each of the source region and the drain region is higher than an impurity concentration of the channel region.

### CROSS REFERENCE TO RELATED APPLICATION

This application is based on Japanese Patent Application. No. 2009-294797 filed on Dec. 25, 2009, the disclosure of which is incorporated herein by reference.

### FIELD OF THE INVENTION

The present invention relates to a semiconductor device having a JFET and a method for manufacturing a semiconductor device having a JFET.

### BACKGROUND OF THE INVENTION

Conventionally, in U.S. Pat. No. 7,560,325, a JFET is made from SiC, which is suitably used for a high frequency and high breakdown voltage device. FIG. 11 shows a cross sectional view of the JFET. As shown in FIG. 11, a P conductive type buffer layer J2, a N conductive type channel layer J3 and a N conductive type layer J4 are stacked in this order on a substrate J1 made of SiC. Then, a concavity J5 is formed from a surface of the N conductive type layer J4 to reach the channel layer J3 by an etching process. A P conductive type gate region J7 is formed in the concavity J5 via a P conductive type layer J6. Further, a source electrode J9 and a drain electrode J10 are formed on the N conductive type layer J4 via a metal layer J8. The source electrode J9 and the drain electrode J10 are separated apart from the gate region J7. Thus, the JFET is prepared.

In the JFET in U.S. Pat. No. 7,560,325, when the gate region J7 directly contacts the N conductive type layer J4, they may provide a PN junction having an interface, at which an impurity concentration is rapidly changed. To avoid this, the gate region J7 is surrounded with the P conductive type layer J6. Accordingly, in this case, a capacitance between the gate region J7 and the N conductive type layer J4 may be large. Specifically, the capacitance between the gate and the source and between the gate and the drain is made large. Thus, the high frequency usage is limited. Further, a depletion layer extends from the P conductive type layer J6 having a low concentration. The device is designed to pinch off the channel layer J3 with using the depletion. Accordingly, when the JFET turns on, it is necessary to apply a high voltage to the gate region J7.

### SUMMARY OF THE INVENTION

In view of the above-described problem, it is an object of the present disclosure to provide a semiconductor device having a JFET. It is another object of the present disclosure to provide a manufacturing method of a semiconductor device having a JFET. The semiconductor device has a low capacitance between a gate and source and/or a low capacitance between a gate and a drain. Further, a gate voltage in a case where the device turns on is reduced.

According to a first aspect of the present disclosure, a semiconductor device having a JFET includes: a substrate made of semi-insulating semiconductor material and having a first surface; a gate region having a first conductive type and disposed in a surface portion of the substrate; a channel region having a second conductive type and disposed on the first surface of the substrate or in another surface portion of the substrate, wherein the channel region is disposed on the gate region, and the channel region contacts the gate region; a source region and a drain region disposed on both sides of the gate region so as to sandwich the channel region, respectively, wherein an impurity concentration of each of the source region and the drain region is higher than an impurity concentration of the channel region; a source electrode electrically coupled with the source region; a drain electrode electrically coupled with the drain region; and a gate electrode electrically coupled with the gate region.

In the above device; since the gate region is embedded in the substrate, a capacitance between the gate and the source and a capacitance between the gate and the drain are reduced. Further, since the gate region contacts directly the channel layer, a depletion layer extending from the gate region easily pinches off the channel layer. Thus, a gate voltage for turning on the JFET is restricted.

According to a second aspect of the present disclosure, a manufacturing method of a semiconductor device having a JFET includes: preparing a substrate made of semi-insulating semiconductor material and having a first surface; implanting a first conductive type impurity ion in a surface portion of the substrate so as to form a gate region; forming a channel region having a second conductive type on the first surface of the substrate or in another surface portion of the substrate, wherein the channel region is disposed on the gate region, and the channel region contacts the gate region; forming a source region having the second conductive type and a drain region having the second conductive type on both sides of the gate region so as to sandwich the channel region, respectively, wherein an impurity concentration of each of the source region and the drain region is higher than an impurity concentration of the channel region; forming a source electrode electrically coupled with the source region; forming a drain electrode electrically coupled with the drain region; and forming a gate electrode electrically coupled with the gate region.

In the above method, since the gate region is embedded in the substrate, a capacitance between the gate and the source and a capacitance between the gate and the drain are reduced. Further, since the gate region contacts directly the channel layer, a depletion layer extending from the gate region easily pinches off the channel layer. Thus, a gate voltage for turning on the JFET is restricted.

### BRIEF DESCRIPTION OF THE DRAWINGS

The above and other objects, features and advantages of the present invention will become more apparent from the following detailed description made with reference to the accompanying drawings. In the drawings:

FIG. 1 is a diagram showing a cross sectional view of a SiC semiconductor device having a JFET according to a first embodiment;

FIGS. 2A to 4C are diagrams showing a manufacturing method of the device in FIG. 1;

FIG. 5 is a diagram showing a cross sectional view of a SiC semiconductor device having a JFET according to a second embodiment;

FIG. 6 is a diagram showing a cross sectional view of a SiC semiconductor device having a JFET according to a third embodiment;

FIGS. 7A to 7D are diagrams showing a manufacturing method of the device in FIG. 6;

FIG. 8 is a diagram showing a cross sectional view of a SiC semiconductor device having a JFET according to a fourth embodiment;

FIG. 9 is a diagram showing a cross sectional view of a SiC semiconductor device having a JFET according to a fifth embodiment;

FIG. 10 is a diagram showing a cross sectional view of a SiC semiconductor device having a JFET according to a sixth embodiment; and

FIG. 11 is a diagram showing a cross sectional view of a SiC semiconductor device, having a JFET according to a prior art.

### DETAILED DESCRIPTION OF THE PREFERRED, EMBODIMENTS

### First Embodiment

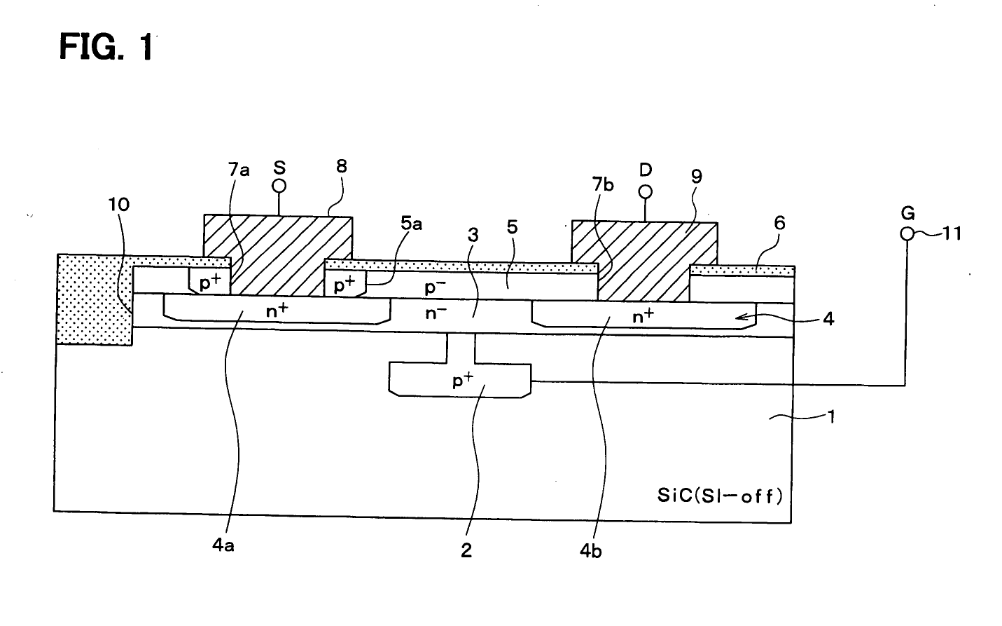

FIG. 1 shows a SiC semiconductor device having a JFET according to a first embodiment. A structure of the JFET in the SiC semiconductor device will be explained.

The device is made from a SiC substrate 1 having a principal surface, which is tilted by an offset angle with respect to a C-orientation plane, i.e., a (000-1)-orientation plane, or a silicon plane, i.e., a (0001)-orientation Si plane so that the SiC substrate 1 provides an offset substrate. The SiC substrate 1 is a semi-insulating substrate. Here, the semi-insulating property means that the substrate 1 has a resistance near the insulating material although the substrate is made of semiconductor material. Specifically, the substrate 1 is made from a non-dope semiconductor material. For example, the SiC substrate 1 has a resistance in a range between 1×10¹⁰Ω·cm and 1×10¹¹Ω·cm. The thickness of the substrate 1 is in a range between 50 and 400 micrometers. Specifically, the thickness of the substrate is 350 micrometers.

A P conductive type gate region 2 is formed in a surface portion of the substrate 1. The gate region 2 has a reverse T shape so that a center portion of the gate region 2 has a convexity. The P conductive type impurity concentration is in a range between 5×10¹⁸ cm⁻³ and 5×10¹⁹ cm⁻³. Specifically, the P conductive type impurity concentration is 1×10¹⁹ cm⁻³. A depth from a top end of the convexity is in a range between 0.1 and 0.5 micrometers. Specifically, the depth of the gate region 2 is 0.4 micrometers. Thus, the gate region 2 is embedded in the substrate 1.

A N conductive type channel layer 3 is formed over the gate region 2 in the substrate 1. The channel of the device is formed in the channel layer 3. The channel layer 3 has a N conductive type impurity concentration in a range between 1×10¹⁶ cm⁻³ and 1×10¹⁸ cm⁻³. Specifically, the N conductive type impurity concentration is 1×10¹⁷ cm⁻³. The thickness of the channel layer 3 is in a range between 0.1 and 1.0 micrometers. Specifically, the thickness of the channel layer 3 is 0.4 micrometers.

A N conductive type layer 4 is formed in the channel layer 3 from the surface of the channel layer 3 to a predetermined depth position. The N conductive type layer 4 is separated into a right part and a left part, which are disposed on both sides of the gate region 2. The left part of the N conductive type layer 4 provides a N conductive type source region 4a, and the right part of the N conductive type layer 4 provides a N conductive type drain region 4b. The source region 4a and the drain region 4b have a N conductive type impurity concentration in a range between 5×10¹⁸ cm⁻³ and 1×10²⁰ cm⁻³. Specifically, the N conductive type impurity concentration of the source region 4a and the drain region 4b is 2×10¹⁹ cm⁻³. The thickness of the source region 4a and the drain region 4b is in a range between 0.1 and 1.0 micrometers. Specifically, the thickness of the source region 4a and the drain region 4b is 0.4 micrometers.

A P conductive type buffer layer 5 is formed on the surface of the channel layer 3 and the N conductive type layer 4. The buffer layer 5 functions to improve a breakdown voltage of the device. A P conductive type impurity concentration of the buffer layer 5 is in a range between 1×10¹⁶ cm⁻³ and 1×10¹⁷ cm⁻³. Specifically, the P conductive type impurity concentration of the buffer layer 5 is 1×10¹⁶ cm⁻³. The thickness of the buffer layer is in a range between 0.2 and 2.0 micrometers. Specifically, the thickness of the buffer layer is 0.4 micrometers. Further, a P conductive type contact region 5a is formed in a part of the buffer layer 5, which is disposed on the surface of the source region 4a.

Further, an interlayer insulation film 6 made of a ONO film or a AlN film is formed on the surface of the buffer layer 5. A first concavity 7a is formed such that the first concavity 7a penetrates the interlayer insulation film 6 and the contact region 5a, and reaches the source region 4a. The second concavity 7b is formed such that the second concavity 7b penetrates the interlayer insulation film 6 and the buffer layer 5, and reaches the drain region 4b. The source electrode 8 is electrically coupled with the source region 4a via the first concavity 7a. The drain electrode 9 is electrically coupled with the drain region 4b via the second concavity 7b. The source electrode 8 and the drain electrode 9 are made of multiple metal layers so that they have a stacking structure of metal layers. For example, a Ni series metal layer, Ti series metal layer and an aluminum wiring layer or a gold layer are stacked in this order so that the stacking structure is formed. The Ni series metal layer such as a NiSi₂ film contacts the N conductive type SiC with ohmic contact. The gold layer is suitably used for coupling with a wire, which electrically couples with an external circuit. The Ni series metal layer has a thickness in a range between 0.1 and 0.5 micrometers. The thickness of the Ti series metal layer is in a range between 0.1 and 0.5 micrometers. The thickness of the aluminum wiring layer or the gold layer is in a range between 1.0 and 5.0 micrometers. Specifically, the thickness of the Ni series metal layer is 0.2 micrometers, the thickness of the Ti series metal layer is 0.1 micrometers, and the thickness of the aluminum wiring layer or the gold layer is 3.0 micrometers.

A concavity 10 is spaced apart from a JFET forming region. The concavity 10 provides an element separation structure to separate the JFET from other regions of the device.

A gate electrode 11 is formed on the surface of the gate region 2. The gate electrode 11 is not shown in FIG. 1. The gate electrode 11 is also made of multiple metal layers having a stacking structure. The gate electrode 11 has the same structure as the source electrode 8 and the drain electrode 9.

Thus, the JFET is formed. An interlayer insulation film and/or a protection film made of silicon oxide film and a silicon nitride film electrically isolate each electrode. The SiC semiconductor device is completed.

In the JFET in the SiC semiconductor device, when a gate voltage is not applied to the gate electrode 11, a depletion layer extending from the gate region 2 toward the channel layer 3 and another depletion layer extending from the buffer layer 5 toward the channel layer 3 pinch off the channel layer 3. Under this state, when the gate voltage is applied to the gate electrode 11, the depletion layer extending from the gate region 2 is reduced. Thus, the channel is formed in the channel layer 3. The current flows between the source electrode 8 and the drain electrode 9 through the channel in the channel layer 3. Thus, the JFET functions as a normally off element.

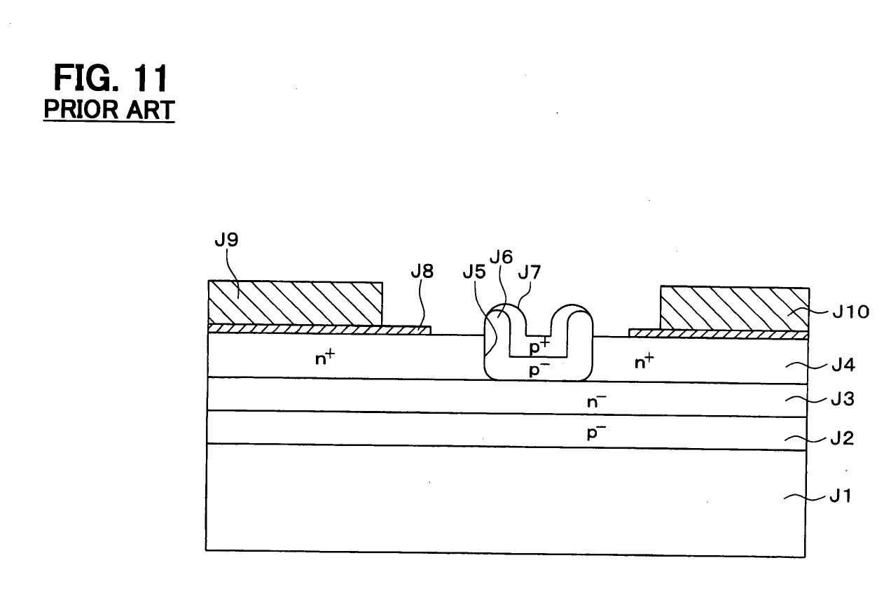

In the above JFET, the gate region 2 is embedded in the substrate 1. Accordingly, compared with a conventional structure shown in FIG. 11 such that the gate region J7 is disposed on the surface of the substrate, and the P conductive type layer J6 having the impurity concentration lower than the gate region J7 is formed between the gate region J7 and the channel layer J3, the capacitance between the gate and source and the capacitance between the gate and the drain are reduced. Further, since the gate region 2 directly contacts the channel layer 3, the depletion layer extending from the gate region 2 easily pinch off the channel layer 3. Thus, the gate voltage for turning on the JFET is reduced.

Further, although the gate region 2 has the reverse T shape with the partial convexity, a whole of the upper portion of the gate region 2 may contact the channel layer 3. In the present embodiment, since the gate region 2 has the partial convexity, the area of the gate region 2 contacting the channel layer 3 is minimized. Accordingly, when the channel length is short, the cut-off frequency is made high. Accordingly, the SiC semiconductor device having the JFET is suitably used for high frequency.

Since the SiC substrate 1 is a semi-insulating substrate, the electric wave generated in the operation of the JFET is absorbed. Thus, the SiC semiconductor device having the JFET is suitably used for high frequency. Since the buffer layer 5 is formed on the surface of the substrate 1, the electric wave generated in the operation of the JFET is much absorbed. The SiC semiconductor device having the JFET is suitably used for high frequency. The buffer layer 5 is electrically coupled with the source electrode 8 via the contact layer 5a so that the buffer layer 5 is grounded. The electric potential of the buffer layer 5 is fixed to the ground potential.

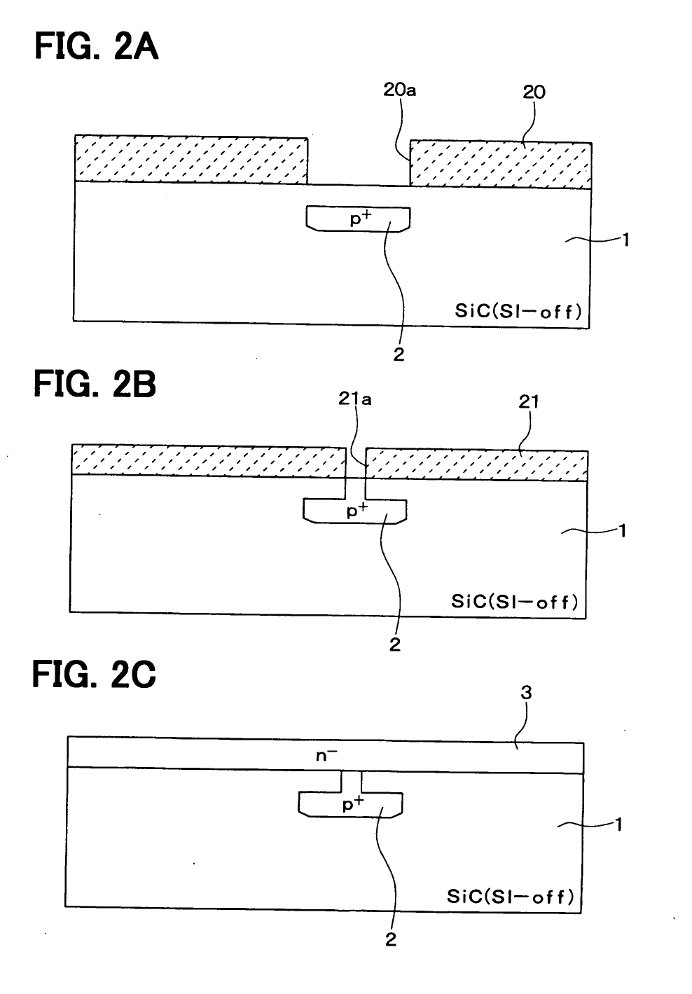

Next, the manufacturing method of the SiC semiconductor device having the JFET will be explained. FIGS. 2A to 4C show the manufacturing method of the device.

(Step in FIG. 2A)

The SiC substrate 1 having the semi-insulating property is prepared. The substrate 1 includes a principal surface, which is tilted by an offset angle with respect to the C-orientation plane or a Si-plane. Here, the C-orientation plane represents a (000-1)-orientation plane, and the Si-plane represents a (0001)-orientation plane. A mask 20 made of LTO or the like is formed on the principal surface of the substrate 1. Then, the mask 20 is patterned so that an opening 20a is formed in the mask 20. The opening 20a corresponds to a base portion of the gate region 2, which is disposed under the convexity of the gate region 2. A P conductive type impurity is implanted through the opening 20a of the mask 20 by an ion implantation method. Thus, the base portion of the gate region 2 having the P conductive type impurity concentration in a range between 5×10¹⁸ cm⁻³ and 5×10¹⁹ cm⁻³ is formed; in the substrate 1. Specifically, the P conductive type impurity concentration of the base portion is 1×10¹⁹ cm⁻³. The thickness of the base portion is in a range between 0.1 and 0.5 micrometers. Specifically, the thickness of the base portion is 0.2 micrometers.

(Step in FIG. 2B)

After the mask 20 is removed, another mask 21 made of LTO or the like is formed on the principal surface of the substrate 1. Then, the mask 21 is patterned so that another opening 21a is formed in the mask 21. The opening 21a corresponds to the convexity of the gate region 2. The P conductive type impurity is implanted through the opening 21a of the mask 21 by the ion implantation method. The convexity of the gate region 2 is formed such that the P conductive type impurity concentration is in a range between 5×10¹⁸ cm⁻³ and 5×10¹⁹ cm⁻³, and the thickness of the convexity is in a range between 0.1 and 0.5 micrometers. Specifically, the P conductive type impurity concentration of the convexity is 1×10¹⁹ cm⁻³, and the thickness of the convexity is 0.2 micrometers.

(Step in FIG. 2C)

After the mask 21 is removed, the channel layer 3 is formed on the substrate 1 by an epitaxial growth method. The N conductive type impurity concentration of the channel layer 3 is in a range between 1×10¹⁶ cm⁻³ and 1×10¹⁸ cm⁻³, and the thickness of the channel layer 3 is in a range between 0.1 and 1.0 micrometers. Specifically, the N conductive type impurity concentration of the channel layer 3 is 1×10¹⁷ cm⁻³, and the thickness of the channel layer 3 is 0.4 micrometers.

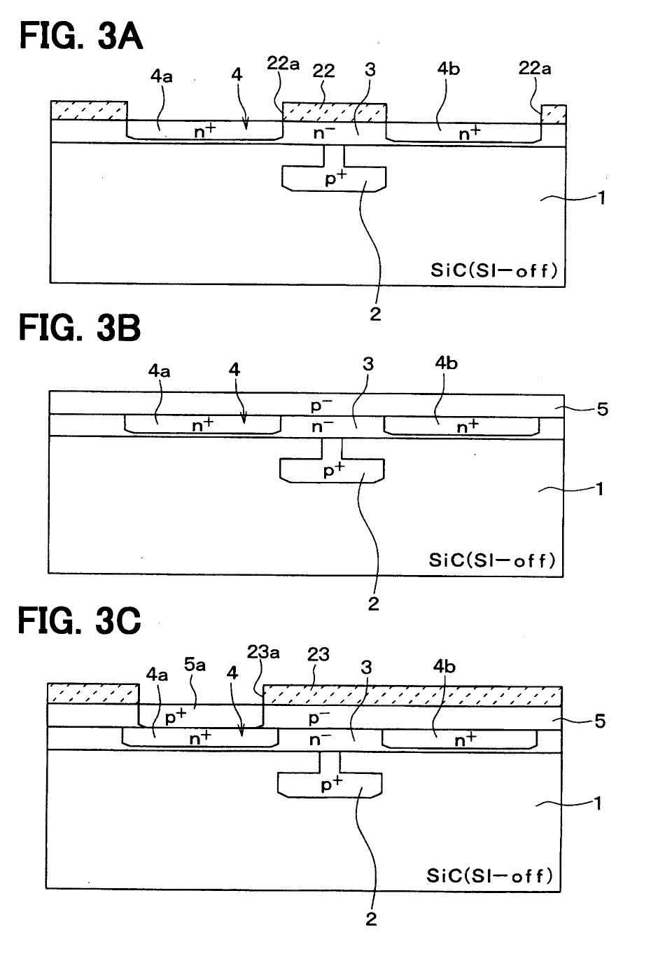

(Step in FIG. 3A)

After the mask 21 is removed, another mask 22 made of LTO or the like is formed on the surface of the channel layer 3. Then, the mask is patterned so that another opening 22a is formed on a source-region-to-be-formed region and a drain-region-to-be-formed region of the channel layer 3. Then, the N conductive type impurity is implanted through the opening 22a of the mask 22 by the ion implantation method. The N conductive type impurity concentration of the source region 4a and the drain region 4b is in a range between 5×10¹⁸ cm⁻³ and 1×10²⁰ cm⁻³, and the thickness of the source region 4a and the drain region 4b is in a range between 0.1 and 1.0 micrometers. Specifically, the N conductive type impurity concentration of the source region 4a and the drain region 4b is 2×10¹⁹ cm⁻³, and the thickness of the source region 4a and the drain region 4b is 0.4 micrometers.

(Step in FIG. 3B)

After the mask 22 is removed, the buffer layer 5 is formed on the surface of the channel layer 3, the surface of the source region 4a and the surface of the drain region 4b by the epitaxial growth method. The P conductive type impurity concentration of the buffer layer 5 is in a range between 1×10¹⁶ cm⁻³ and 1×10¹⁷ cm⁻³, and the thickness of the buffer layer 5 is in a range between 0.2 and 2.0 micrometers. Specifically, the P conductive type impurity concentration of the buffer layer 5 is 1×10¹⁶ cm⁻³, and the thickness of the buffer layer 5 is 0.4 micrometers.

(Step in FIG. 3C)

After a mask 23 is formed on the surface of the buffer layer 5, the mask is patterned so that an opening 23a is formed on a contact-region-to-be-formed region in the buffer layer 5. A P conductive type impurity is implanted through the opening 23a of the mask 23 by the ion implantation method. Thus, the contact region 5a is formed in the buffer layer 5. The P conductive type impurity concentration of the contact region 5a is in a range between 1×10¹⁶ cm⁻³ and 1×10¹⁷ cm⁻³, and the thickness of the contact region 5a is in a range between 0.2 and 2.0 micrometers. Specifically, the P conductive type impurity concentration of the contact region 5a is 1×10¹⁶ cm⁻³, and the thickness of the contact region 5a is 0.4 micrometers. After, that, the mask 23 is removed, and then, with using an etching mask (not shown), a groove (not shown) for contact is formed such that the groove penetrates the buffer layer 5 and the channel layer 3 and reaches the gate region 2. The groove is shown in a cross sectional view, which is different from the cross section in FIG. 3C.

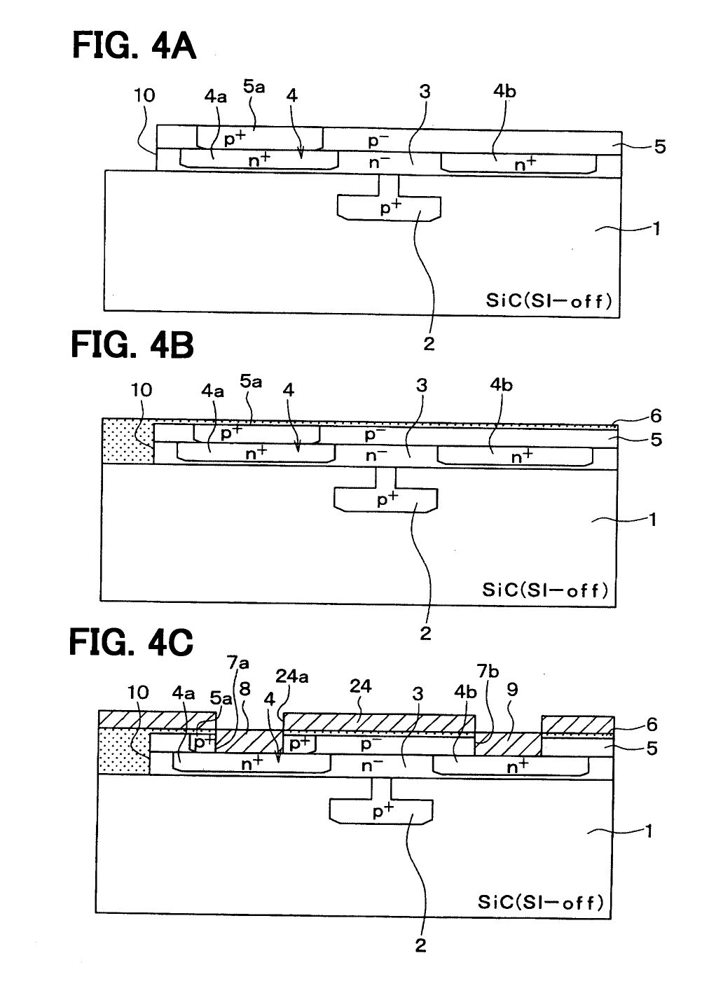

(Step in FIG. 4A)

An etching mask (not shown) is arranged so that the concavity 10 is formed on the buffer layer 5. The concavity 10 penetrates the buffer layer 5 and the channel layer 3, and reaches the substrate 1. The concavity 10 functions as an element separation structure for separating the JFET from other regions.

(Step in FIG. 4B)

A silicon oxide film is deposited so that the interlayer insulation film 6 is formed on the surface of the buffer layer 5 and the surface of the contact region 5a and in the concavity 10.

(Step in FIG. 4C)

After the mask 24 is arranged on the surface of the interlayer insulation film 6, the mask 24 is patterned so that the opening 24a is formed on a gate-electrode-to-be-formed region, a source-electrode-to-be-formed region and a drain-electrode-to-be-formed region. Then, a selective etching process is performed with using the opening 24a of the mask 24, so that the first concavity 7a is formed such that the first concavity 7a penetrates the interlayer insulation film 6 and the contact region 5a and reaches the source region 4a, and the second concavity 7b is formed such that the second concavity 7b penetrates the interlayer insulation film 6 and the buffer layer 5 and reaches the drain region 4b. Further, a Ni series metal layer is formed on the mask 24, and then, the mask 24 is removed so that the unnecessary part of the Ni series metal layer is lifted off, i.e., removed. Thus, the Ni series metal layer is arranged on the gate-electrode-to-be-formed region, the source-electrode-to-be-formed region and the drain-electrode-to-be-formed region. Then, a thermal treatment process is performed so that silicide reaction is generated in order to form a NiSi₂ film. The NiSi₂ film provides an ohmic contact.

After that, the Ti series metal layer is deposited, and then, patterned. Further, the aluminum wiring layer or the gold layer is formed. Another interlayer insulation film and/or a protection film are formed. Thus, the SiC semiconductor device having the JFET is manufactured.

The SiC semiconductor device having the JFET has a structure such that the gate region 2 is embedded in the substrate 1. Accordingly, the capacitance between the gate and the source and/or the capacitance between the gate and the drain are reduced. Since the gate region 2 directly contacts the channel layer 3, the depletion layer extending the gate region 2 easily pinches off the channel layer 3. Thus, the gate voltage to be applied to the gate when the JFET turns on is improved.

### Second Embodiment

A second embodiment will be explained. A SiC semiconductor device according to the second embodiment has no buffer layer 5.

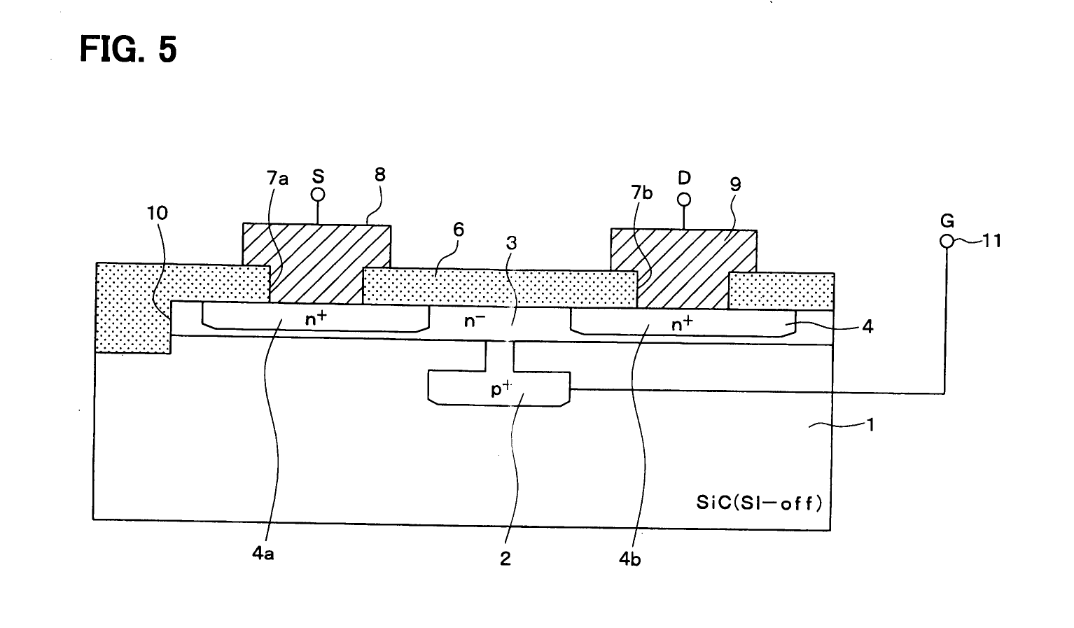

FIG. 5 shows the SiC semiconductor device having the JFET according to the present embodiment. As shown in FIG. 5, the interlayer insulation film 6 directly formed on the surface of the channel layer 3 without forming the buffer layer 5.

In the above structure, the effects similar to the first embodiment are obtained. Since the device does not include the buffer layer 5, the breakdown voltage of the device in FIG. 5 is lower than the first embodiment.

The SiC semiconductor device according to the present embodiment is manufactured by the same method as the first embodiment. A different between the present embodiment and the first embodiment is that a steps for forming the buffer layer 5 and a step for forming the contact layer 5a are skipped since the device does not include the buffer layer 5.

### Third Embodiment

A third embodiment will be explained. In a SiC semiconductor device according to the present embodiment, the source region 4a and the drain region 4b are formed by an epitaxial growth method.

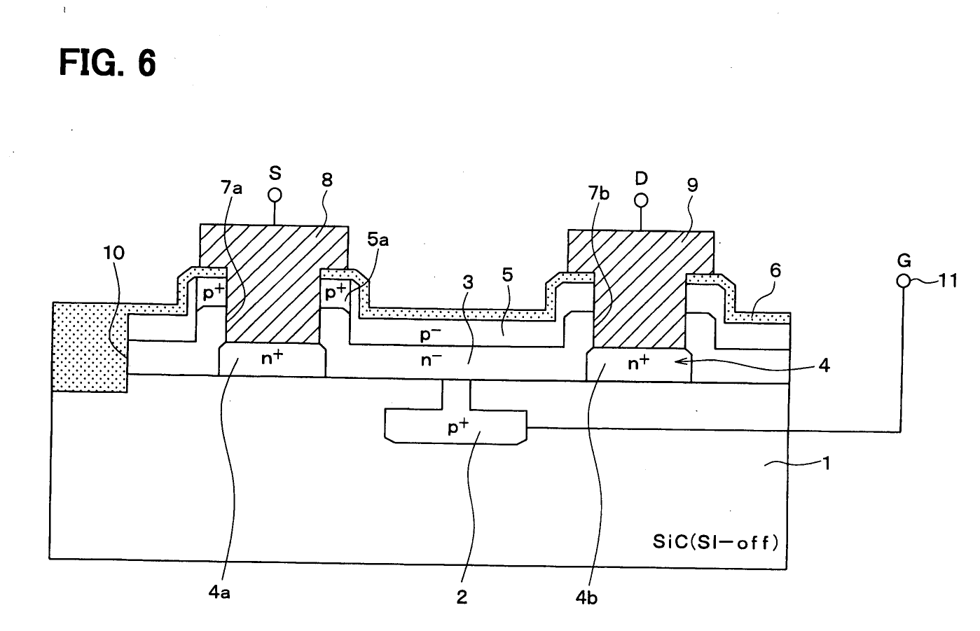

FIG. 6 shows the SiC semiconductor device having the JFET according to the present embodiment. As shown in FIG. 6, the source region 4a and the drain region 4b are formed by the epitaxial growth method. The channel layer 3 is formed on the surface of the source region 4a and the surface of the drain region 4b. Further, the channel layer 3 includes a convexity, which is disposed on the source region 4a and the drain region 4b. Further, the buffer layer 5 and the interlayer insulation film 6 are convexed at the convexity of the channel layer 3. The contact region 5a is formed at the convexity of the buffer layer 5, which is disposed over the source region 4.

In the above structure, the concavities 7a, 7b penetrate the channel layer 3 so that the concavities 7a, 7b reach the source, region 4a and the drain region 4b, respectively. The source electrode 8 and the drain electrode 9 contact the channel layer 3. Even when the source electrode 8 and the drain electrode 9 contact the channel layer 3, no difficulty is generated. Thus, even when the source region 4a and the drain region 4b are formed by the epitaxial growth process, the effects similar to the first embodiment are obtained.

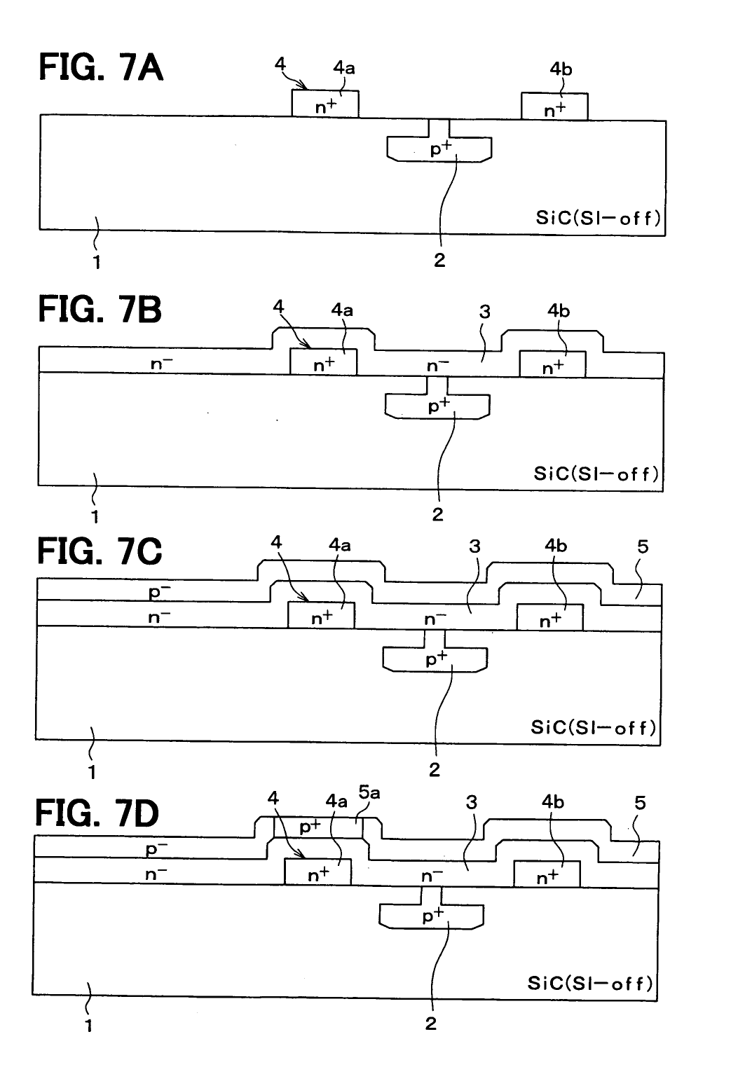

Next, the manufacturing method of the SiC semiconductor device with the JFET will be explained. FIGS. 7A to 7D show a part of the manufacturing method of the SiC semiconductor device. The other part of the manufacturing method is similar to the first embodiment, and therefore, the other part is not shown in FIGS. 7A to 7D.

Firstly, the steps shown in FIGS. 2A and 2B are performed, so that the gate region 2 is formed in the SiC substrate 1. Then, a step shown in FIG. 7A is performed such that the N conductive type layer 4 is formed on the principal surface of the substrate 1. Then, the N conductive type layer 4 is patterned. Thus, the source region 4a and the drain region 4b are formed. Then, in a step in FIG. 7B, the channel layer 3 is deposited on the principal surface of the substrate 1 including the surface of the source region 4a and the surface, of the drain region 4b. Then, in a step 7C, the buffer layer 5 is deposited on the surface of the channel layer 3. Then, in a step in FIG. 7D, similar to the step in FIG. 3C, the contact region 5a is formed in the buffer layer 5. Then, the steps in FIGS. 4A to 4C are performed, so that the SiC semiconductor device according to the present embodiment is completed.

Thus, even when the source region 4a and the drain region 4b are formed by the epitaxial growth method, the effects similar to the first embodiment are obtained.

### Fourth Embodiment

A fourth embodiment will be explained. A SiC semiconductor device according to the present embodiment includes no buffer layer 5, compared with the device according to the third embodiment.

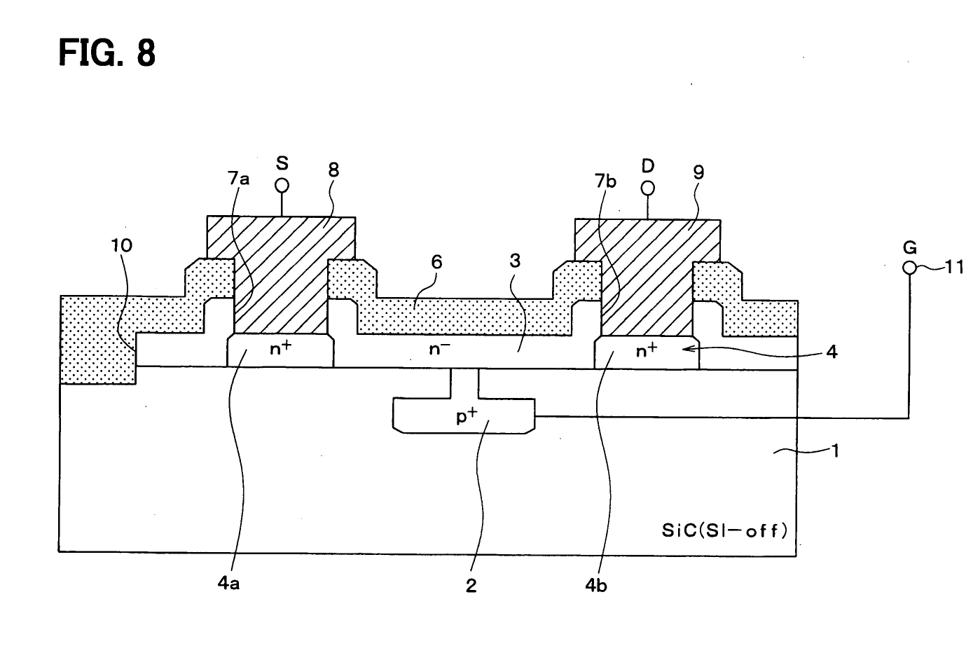

FIG. 8 shows the device having the JFET according to the present embodiment. As shown in FIG. 8, the interlayer insulation film 6 is directly formed on the surface of the channel layer 3 without forming the buffer layer 5.

In the above structure, the effects similar to the third embodiment are obtained. However, since the device includes no buffer layer 5, the breakdown voltage of the device according to the present embodiment is lower than that according to the third embodiment.

Here, the manufacturing method of the device according to the present embodiment is similar to that according to the third embodiment. A difference between the present embodiment and the third embodiment is such that the step for forming the buffer layer 5 and the step for forming the contact region 5a are skipped.

### Fifth Embodiment

A fifth embodiment will be explained. In a SiC semiconductor device according to the present embodiment, the formation position of the source electrode 8 and the drain electrode 9 is changed.

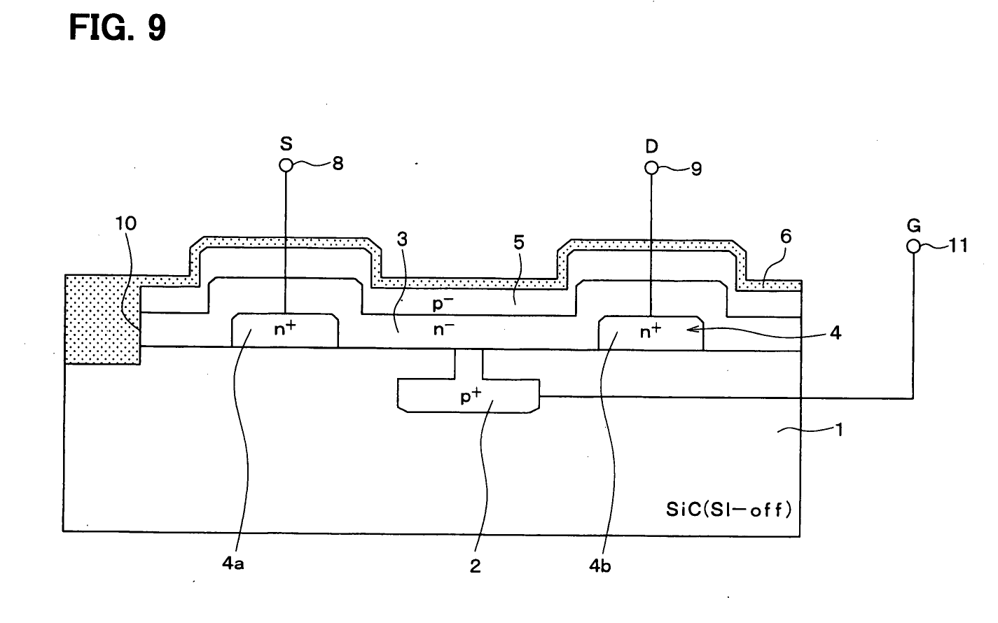

FIG. 9 shows the SiC semiconductor, device having the JFET according to the present embodiment. As shown in FIG. 9, the source region. 4a and the drain region 4b are retrieved to the outside of the cell region so that the source region 4a and the drain region 4b are electrically coupled with the source electrode 8 and the drain electrode 9, respectively, at connection portions, which is shown in a cross sectional view, which is different from the cross section in FIG. 9. In the above structure, the similar effects of the third embodiment are obtained.

The manufacturing method of the device according to the present embodiment is similar to that according to the third embodiment. A difference between the present embodiment and the third embodiment is such that the mask for forming the source region 4a and the drain region 4b and the mask for forming the source electrode 8 and the drain electrode 9 in the present embodiment are different from those in the third embodiment since the layout of the source region 4a and the drain region 4b and the layout of the source electrode 8 and the drain electrode 9 in the present embodiment are different from those in the third embodiment.

### Sixth Embodiment

A sixth embodiment will be explained. A SiC semiconductor device according to the present embodiment includes no buffer layer 5.

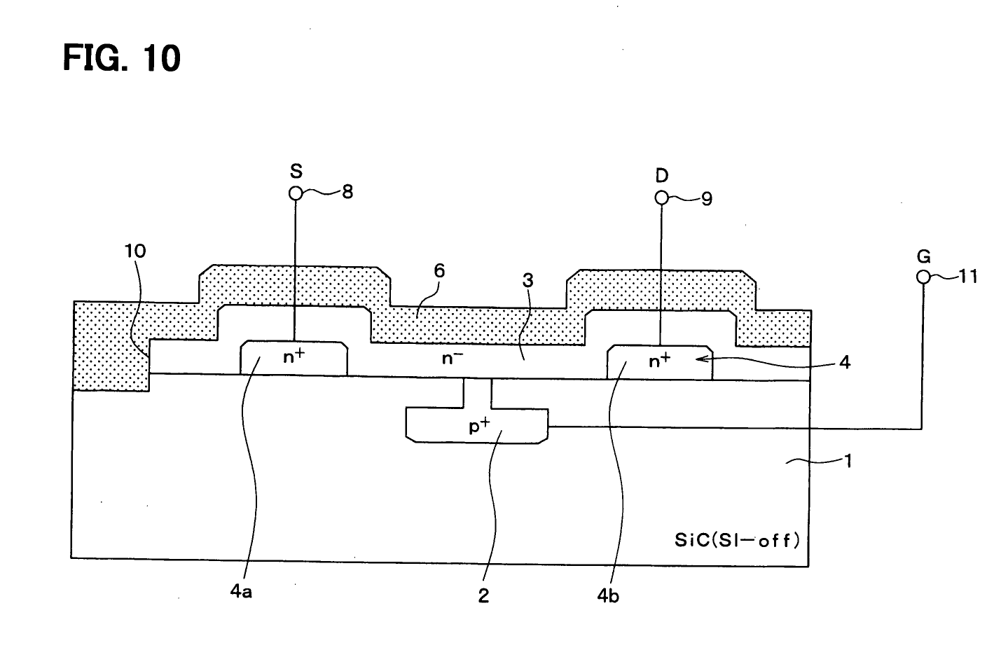

FIG. 10 shows the SiC semiconductor device having the JFET according to the present embodiment. As shown in FIG. 10, in the present embodiment, the interlayer insulation film 6 is directly formed on the surface of the channel layer 3 without forming the buffer layer 5.

In the above structure, the effects similar to the fifth embodiment are obtained. However, since the device according to the present embodiment does not include the buffer layer 5, the breakdown voltage of the present embodiment is lower than that of the fifth embodiment.

The manufacturing method of the device according to the present embodiment is similar to that of the fifth embodiment. A difference between the present embodiment and the fifth embodiment is such that the step for forming the buffer layer 5 and the step for forming the contact layer 5a are skipped since the device does not include the buffer layer 5.

### Other Embodiments

In the above embodiments, the channel layer 3 is epitaxially formed on the principal surface of the substrate 1. Alternatively, when the gate region 2 is formed, a part of the substrate 1 disposed over the convexity of the gate region 2 remains. The thickness of the part of the substrate is equal to the thickness of the channel layer 3. Then, the N conductive type impurity is implanted in the part of the substrate 1 by the ion implantation method. Thus, the channel layer 3 is formed in the part of the substrate 1.

In the above embodiments, the channel layer 3 provides N conductive type channel, so that the JFET is a N channel type JFET. Alternatively, the N conductive type and the P conductive type may be exchanged so that the P channel type JFET is obtained.

In the above embodiments, the semiconductor device is the SiC semiconductor device. Alternatively, the semiconductor device may be a Si semiconductor device. Alternatively, the semiconductor device may be a wide gap semiconductor device.

In the above embodiments, the device includes the JFET. Alternatively, the device may include MESFET.

While the invention has been described with reference to preferred embodiments thereof, it is to be understood that the invention is not limited to the preferred embodiments and constructions. The invention is intended to cover various modification and equivalent arrangements. In addition, while the various combinations and configurations, which are preferred, other combinations and configurations, including more, less or only a single element, are also within the spirit and scope of the invention.

What is claimed is:

1. A semiconductor device having a JFET comprising:
a substrate made of semi-insulating semiconductor material and having a first surface;
a gate region having a first conductive type and disposed in a surface portion of the substrate;
a channel region having a second conductive type and disposed on the first surface of the substrate or in another surface portion of the substrate, wherein the channel region is disposed on the gate region, and the channel region contacts the gate region;
a source region and a drain region disposed on both sides of the gate region so as to sandwich the channel region, respectively, wherein an impurity concentration of each of the source region and the drain region is higher than an impurity concentration of the channel region;
a source electrode electrically coupled with the source region;
a drain electrode electrically coupled with the drain region; and
a gate electrode electrically coupled with the gate region.

2. The semiconductor device according to claim 1,
wherein the semi-insulating semiconductor material is silicon carbide having a wide gap.

3. The semiconductor device according to claim 1,
wherein the gate region has a convexity, which protrudes toward the channel region, and
wherein the convexity contacts the channel region.

4. The semiconductor device according to claim 1, further comprising:
a buffer layer disposed on the channel region,
wherein the buffer layer has the first conductive type, and
wherein an impurity concentration of the buffer layer is lower than the gate region.

5. The semiconductor device according to claim 4, further comprising:
a contact region disposed in the buffer layer and having the first conductive type,
wherein the contact region has an impurity concentration, which is higher than the buffer layer, and
wherein the buffer layer contacts the source electrode via the contact region.

6. The semiconductor device according to claim 1,
wherein the source region and the drain region are made from an epitaxial second conductive type layer, which is epitaxially grown on the substrate, and
wherein the channel region partially covers the source region and the drain region.

7. The semiconductor device according to claim 3,
wherein the gate region further includes a base, from which the convexity protrudes,
wherein the gate region is embedded in the substrate, and
wherein the source region is disposed in a surface portion of the channel region, and the drain region is disposed in another surface portion of the channel region.

8. The semiconductor device according to claim 7,
wherein the source region is embedded in the channel region so that the source region does not contact the substrate,
wherein the drain region is embedded in the channel region so that the drain region does not contact the substrate,
wherein the source region has a second conductive type, the drain region has the second conductive type, and the channel region has the second conductive type, and
wherein an impurity concentration of each of the source region and the drain region is higher than the channel region.

9. The semiconductor device according to claim 8, further comprising:
a buffer layer disposed on the channel region, the source region and the drain region and having the first conductive type,
a contact region disposed in the buffer layer and having the first conductive type,
wherein an impurity concentration of the buffer layer is lower than the gate region,
wherein the contact region has an impurity concentration, which is higher than the buffer layer,
wherein the buffer layer includes a first concavity and a second concavity,
wherein the first concavity penetrates the buffer layer and reaches the source region, and the second concavity penetrates the buffer layer and reaches the drain region,
wherein the source electrode is disposed in the first concavity, and the drain electrode is disposed in the second concavity, and
wherein the contact region is disposed on a sidewall of the first concavity so that the buffer layer contacts the source electrode via the contact region.

10. A manufacturing method of a semiconductor device having a JFET comprising:
preparing a substrate made of semi-insulating semiconductor material and having a first surface;
implanting a first conductive type impurity ion in a surface portion of the substrate so as to form a gate region;
forming a channel region having a second conductive type on the first surface of the substrate or in another surface portion of the substrate, wherein the channel region is disposed on the gate region, and the channel region contacts the gate region;
forming a source region having the second conductive type and a drain region having the second conductive type on both sides of the gate region so as to sandwich the channel region, respectively, wherein an impurity concentration of each of the source region and the drain region is higher than an impurity concentration of the channel region;
forming a source electrode electrically coupled with the source region;
forming a drain electrode electrically coupled with the drain region; and
forming a gate electrode electrically coupled with the gate region.

11. The manufacturing method of the semiconductor device according to claim 10,
wherein the forming of the channel region includes:
epitaxially growing a second conductive type layer on the first surface of the substrate, or implanting a second conductive type impurity ion in another surface portion of the substrate.

12. The manufacturing method of the semiconductor device according to claim 10,
wherein the forming of the source region and the drain region is performed after the forming of the channel region,
wherein the forming of the source region and the drain region includes:
implanting a second conductive type impurity ion into the channel region so as to form the source region and the drain region.

13. The manufacturing method of the semiconductor device according to claim 10,
wherein the forming of the source region and the drain region is performed before the forming of the channel region,
wherein the forming of the source region and the drain region includes:
depositing a second conductive type film on the first surface of the substrate; and
patterning the second conductive type film to form the source region and the drain region,
wherein the forming of the channel region includes:
depositing the channel region on the source region and the drain region.

14. The manufacturing method of the semiconductor device according to claim 10, further comprising:
forming a buffer layer having the first conductive type on the channel region.

15. The manufacturing method of the semiconductor device according to claim 14, further comprising:
implanting a first conductive type impurity ion into the buffer layer so as to form a contact region,
wherein the contact region has an impurity concentration higher than the buffer layer,
wherein, in the forming of the source electrode, the source electrode is coupled with the buffer layer via the contact region.
